(19) United States
(12) Patent Application Publication
(10) Pub. No.: US 2026/0051876 A1
(43) Pub. Date: Feb. 19, 2026

(54) INDUCTIVE LOAD DRIVER WITH PWM REGULATION AND FAST SHUT DOWN CURRENT DECAY

(71) Applicant: STMicroelectronics International N.V., Geneva (CH)

(72) Inventors: Gang JIN, Westland, MI (US); Jennifer CARABOTT, New Hudson, MI (US); Devan TERNAN, Madison Heights, MI (US)

(73) Assignee: STMicroelectronics International N.V., Geneva (CH)

(21) Appl. No.: 19/370,353

(22) Filed: Oct. 27, 2025

Related U.S. Application Data
(63) Continuation of application No. 18/612,022, filed on Mar. 21, 2024, now Pat. No. 12,489,429.

(51) Int. Cl. H03K 3/017; H03K 17/56

(52) U.S. Cl. CPC H03K 3/017; H03K 17/56

(57) ABSTRACT

An inductive load driver provides controlled fast current decay of an inductive load while protecting a gate driver from excessive negative voltages. The driver includes a power stage having a power transistor, a gate driver with gate-drive and source-reference terminals, an active clamping circuit coupled between the gate and source terminals of the transistor, and a semi-active recirculation driver coupled between the output node and ground. A controller selectively operates the circuit in a first mode for pulse-width-modulated load driving and in a second mode for fast current decay. In the second mode, the controller selects between active and passive clamping embodiments based on operating conditions. The active clamping circuit maintains the power transistor in saturation for rapid energy dissipation, while the passive clamping embodiment dissipates energy through a diode network. Both configurations maintain voltages at the gate driver terminals within safe limits during fast-decay operation.

### RELATED APPLICATION

This application is a continuation of U.S. patent application Ser. No. 18/612,022, filed Mar. 21, 2024, the contents of which are incorporated by reference in their entirety.

### TECHNICAL FIELD

This disclosure relates to the field of electronic circuit design and, more specifically, relates to techniques for managing energy in inductive loads, particularly during the transition phases of power converters driving those inductive loads.

### BACKGROUND

Inductive load drivers are commonly used in electronic circuits to drive loads that have inductive characteristics, such as motors, solenoids, and transformers. These loads are characterized by their tendency to resist changes in current, which can lead to potentially damaging voltage spikes when the current is suddenly changed or interrupted. A common challenge in these applications is therefore the management of energy stored in these loads, especially during the transition phases of the power converter driving the load.

One common approach to management of the energy stored in an inductive load involves the use of a standard diode connected to ground to provide for decay of the energy. However, this may not be sufficiently rapid for certain applications, leading to the potential for damage to the components. Therefore, other techniques have been developed.

For example, by clamping the output of the power transistor of the power converter to a large negative voltage, the energy stored in an inductive load may be quickly dissipated. Complicating the issue is that gate drivers to drive the power transistor of the power converter are commonly designed in a way that requires connection to both the gate and source of the power transistor, and the absolute maximum rating (AMR) of the pin connected to the source of the power transistor limits the magnitude of the clamping voltage that may be safely used—for example, the AMR may be on the order of −1V to −14V, whereas a clamping voltage of −24V or lower would be desirable.

Therefore, there exists a need for techniques to effectively manage the decay of energy in inductive loads, particularly in high-demand applications, without exceeding the AMR of the gate driver components and providing for the reliability and longevity of the system.

### SUMMARY

Disclosed herein is an inductive load driver includes a power stage including a power transistor having a gate terminal, a source terminal, and a drain terminal, the drain terminal coupled to a supply voltage and an output node configured to drive an inductive load. The inductive load driver includes a gate driver having a gate-drive output terminal and a source-reference terminal, the gate-drive output terminal coupled to the gate terminal of the power transistor and the source-reference terminal coupled to the source terminal of the power transistor. The inductive load driver includes an active clamping circuit coupled between the gate terminal and the source terminal of the power transistor and also between the gate-drive output terminal and the source-reference terminal of the gate driver, the active clamping circuit being configured to, in a first operating mode, pass a gate-drive voltage from the gate driver to the power transistor, and, in a second operating mode, clamp a voltage between the gate and source terminals to enable fast decay of current in the inductive load while limiting voltage excursions at the gate-drive output terminal and the source-reference terminal. The inductive load driver includes a semi-active recirculation driver coupled between ground and the output node of the power stage, the semi-active recirculation driver being configured to, in the first operating mode, provide a low-impedance current-recirculation path and, in the second operating mode, provide a clamping path for fast-decay current recirculation. The inductive load driver includes a controller configured to control the gate driver, the active clamping circuit, and the semi-active recirculation driver to selectively operate the inductive load driver in the first operating mode or the second operating mode. The active clamping circuit and the semi-active recirculation driver cooperate during the second operating mode to dissipate energy stored in the inductive load while maintaining voltages at the gate-drive output terminal and source-reference terminal of the gate driver within predetermined limits.

In some embodiments, the second operating mode may include either an active-clamping mode or a passive-clamping mode, and the controller may be configured to select between the active-clamping mode and the passive-clamping mode based on a supply-voltage level or an operating condition.

In some embodiments, in the active-clamping mode, the active clamping circuit may include a Zener device and a plurality of resistors arranged to define an adjustable voltage differential between the gate terminal and the source terminal during fast-decay operation.

In some embodiments, in the active-clamping mode, the active clamping circuit may further include an active pull-down circuit configured to establish a gate-to-source voltage that maintains the power transistor in a saturation region during fast-decay operation.

In some embodiments, in the passive-clamping mode, the semi-active recirculation driver may include a Schottky diode and a Zener diode coupled to define an energy-dissipation path during fast-decay operation.

In some embodiments, in the active-clamping mode, the controller may be configured to dynamically adjust a clamping voltage by enabling or disabling a shunting circuit that bypasses a resistor within the active clamping circuit.

In some embodiments, in the active-clamping mode, the active clamping circuit may include a compensation circuit having a resistor having a resistance value selected to adjust a distribution of energy dissipation between the power transistor and the resistor.

In some embodiments, in the passive-clamping mode, the semi-active recirculation driver may include a p-channel transistor configured to selectively connect or disconnect a clamping network from the output node based on a control signal from the controller.

In some embodiments, the controller may be configured to operate in the first operating mode, which is a pulse-width-modulation (PWM) mode for load driving, and the second operating mode, which is a fast-decay mode for current decay, and to transition between the modes by coordinated control of the gate driver and the semi-active recirculation driver.

In some embodiments, the circuit may be configured such that a majority of energy dissipation occurs through the power transistor during the active-clamping mode and through the diode network during the passive-clamping mode.

In some embodiments, the active-clamping and passive-clamping modes may share common circuit nodes and differ by selective inclusion or omission of circuit components.

In some embodiments, the active clamping circuit and the semi-active recirculation driver may be implemented so that negative voltage excursions at the gate-drive output terminal and source-reference terminal of the gate driver are clamped within predetermined limits during the second operating mode.

A system includes a microcontroller configured to generate control signals and the inductive load driver described above. The microcontroller may be configured to dynamically select between the first operating mode and either the active-clamping or passive-clamping embodiment of the second operating mode in response to load conditions or supply voltage.

A method for controlling an inductive load driver having a power transistor, a gate driver, and clamping circuits includes driving the power transistor in a first operating mode that provides pulse-width-modulated current to an inductive load. The method includes, upon termination of the first operating mode, switching to a second operating mode that performs fast current decay. In the second operating mode, the method includes selectively operating in an active-clamping mode, wherein energy from the inductive load is dissipated through the power transistor and a clamping circuit coupled between the gate and source terminals, or a passive-clamping mode, wherein energy from the inductive load is dissipated through a diode network coupled between the output node and ground. The method includes maintaining voltage levels at the gate-driver terminals within safe limits during operation in the second operating mode.

In some embodiments of the method, the fast-decay mode may include either an active-clamping mode or a passive-clamping mode, and the method may further include selecting between active-clamping mode and the passive-clamping mode based on a detected supply-voltage level or operating condition and operating in the selected mode.

In some embodiments of the method, operating in the active-clamping mode may include maintaining the power transistor in a saturation region by applying a controlled gate-to-source voltage using an active pull-down circuit.

In some embodiments of the method, operating in the passive-clamping mode may include recirculating inductive current through a Schottky diode and a Zener diode coupled between the output node and ground.

In some embodiments, the method may further include adjusting a clamping voltage during the active-clamping mode by activating or deactivating a shunting circuit to bypass a resistor within the active clamping circuit.

In some embodiments, the method may further include tuning an energy-dissipation ratio between the power transistor and a resistor in the clamping circuit by selecting a resistance value for the resistor.

In some embodiments of the method, during the fast-decay mode, the method may further include clamping negative voltage excursions at the gate-drive output terminal and source-reference terminal of the gate driver within predetermined limits.

In some embodiments, the method may further include transitioning back from the fast-decay mode to the pulse-width-modulation mode upon completion of a load-decay timer controlled by the controller.

### BRIEF DESCRIPTION OF THE DRAWINGS

FIG. 1 is a block diagram of an inductive load driver disclosed herein.

FIG. 2 is a schematic block diagram of the inductive load driver of FIG. 1.

FIG. 2A is a schematic block diagram of the inductive load driver of FIG. 1, with energy dissipation paths and circuit modifications shown for operation when performing active clamping.

FIG. 2B is a schematic block diagram of the inductive load driver of FIG. 1, with energy dissipation paths and circuit modifications shown for operation when performing passive clamping.

FIG. 3 is a schematic diagram of the inductive load driver of FIG. 1.

FIG. 3A is a schematic diagram of the inductive load driver of FIG. 1, with energy dissipation paths and circuit modifications shown for operation when performing active clamping.

FIG. 3B is a schematic diagram of the inductive load driver of FIG. 1, with energy dissipation paths and circuit modifications shown for operation when performing passive clamping.

FIG. 4 is a state diagram showing operation of the inductive load driver of FIG. 1.

FIG. 5 is a graph showing the gate driver pin voltages and output voltage of the inductive load driver of FIG. 1 during operation in the active clamping configuration where VBATT is stepped at 9V, 18V, 27V, 36V, and 48V.

FIG. 6 is a graph showing the energy dissipation by transistor Q1 and resistor R16 of FIG. 3A during active clamping, for different resistance values of R16 at VBATT=48V.

FIG. 7 is a graph showing the gate driver pin voltages and output voltage of the inductive load driver of FIG. 1 during operation in the passive clamping configuration where VBATT is stepped at 9V, 18V, 27V, 36V, and 48V.

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

Note that in the following description, any resistor or resistance mentioned, except for resistor R7 within the power stage, is a discrete device, unless stated otherwise, and is not simply an electrical lead between two points. Therefore, any resistor or resistance connected between two points has a higher resistance than a lead between those two points, and such resistor or resistance cannot be interpreted as a lead. Similarly, any capacitor or capacitance mentioned is a discrete device, unless stated otherwise, and is not a parasitic element, unless stated otherwise. Additionally, any inductor or inductance mentioned is a discrete device, unless stated otherwise, and is not a parasitic element, unless stated otherwise.

In general, the inductive load driver design described herein provides for fast decay through an active or passive clamping circuit, while protecting pins of the gate driver from excessive negative voltages.

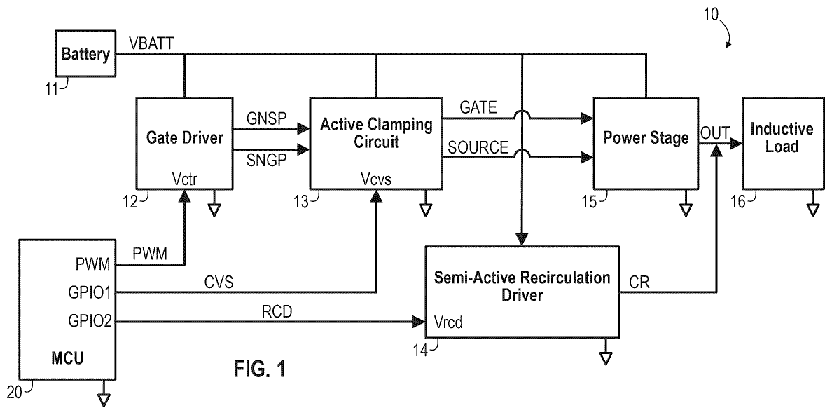

With reference to FIG. 1, the inductive load driver 10 is now described. The inductive load driver 10 includes a power stage 15 (e.g., containing at least one power MOS transistor) connected between a battery 11 (to provide a battery voltage VBATT) and an inductive load 16. A gate driver 12, under control of a pulse width modulation (PWM) signal from a microcontroller (MCU) 20, generates control signals GNSP and SNGP which are respectively coupled to a gate terminal and a source terminal of the power stage 15. An active clamping circuit 13 is coupled between the gate terminal and the source terminal of the power stage 15 and, as will be described, serves to either pass through the gate drive voltage (from output of the Gate Driver 12 across GNSP and SNGP to the input of the Power Stage 15 across GATE and SOURCE) in PWM mode or to actively clamp the voltage at input of the Power Stage 15 across GATE and SOURCE to enable fast decay current recirculation in Fast Decay mode (when the circuit is configured for Active Clamping). A semi-active recirculation driver 14 is coupled between the ground and the output OUT of the power stage 15 and, as will be described, this semi-active recirculation driver 14 serves to either provide a low impedance recirculation path in PWM mode or to passively clamp the output voltage OUT to provide for a fast decay current recirculation path in Fast Decay mode (when the circuit is configured for Passive Clamping).

In operation, the MCU 20 controls the gate driver 12, active clamping circuit 13, and semi-active recirculation driver 14 so as to operate the power stage 15 in either pulse width modulation (PWM) mode or in fast decay mode (in which active or passive clamping is performed at load switchoff).

During operation in PWM mode and in the off period of the PWM cycles, the energy from the inductive load 16 is recirculated through a low impedance recirculation path from ground back to the inductive load provided within a portion of the semi-active recirculation driver 14, which is activated during operation in PWM mode but turned off in fast decay mode. This recirculation in PWM mode, when the load is on (load demand is present), can sufficiently provide for safe operation and prevent overvoltages on the pins of the gate driver 12.

When the load is switched off exiting PWM mode, performance of a fast decay of the inductive load current is desirable (while maintaining the voltage at the pins of the gate driver 12 at safe levels), as it allows for a quick dissipation of the energy within the inductive load. Fast decay may be performed via either active clamping or passive clamping, as stated above.

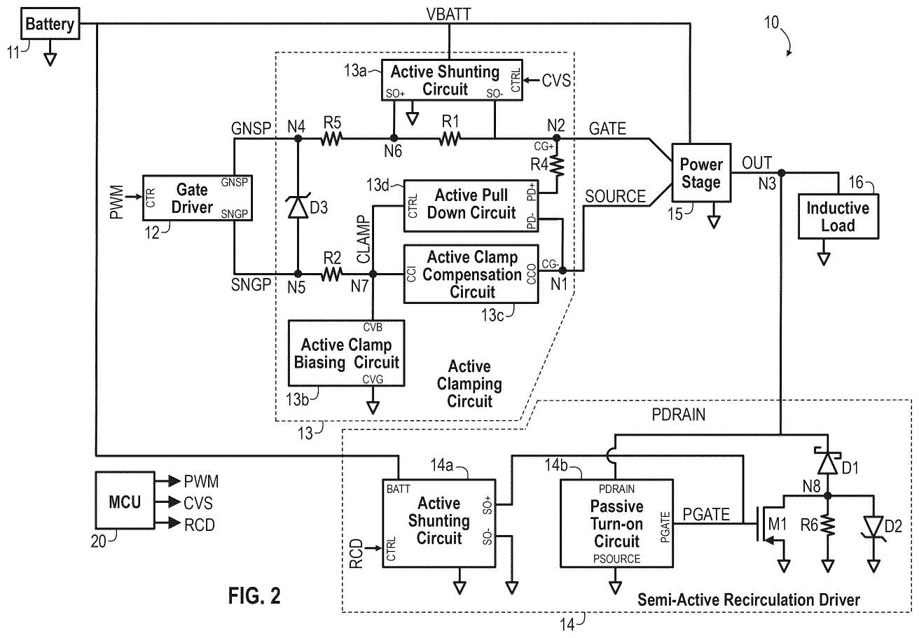

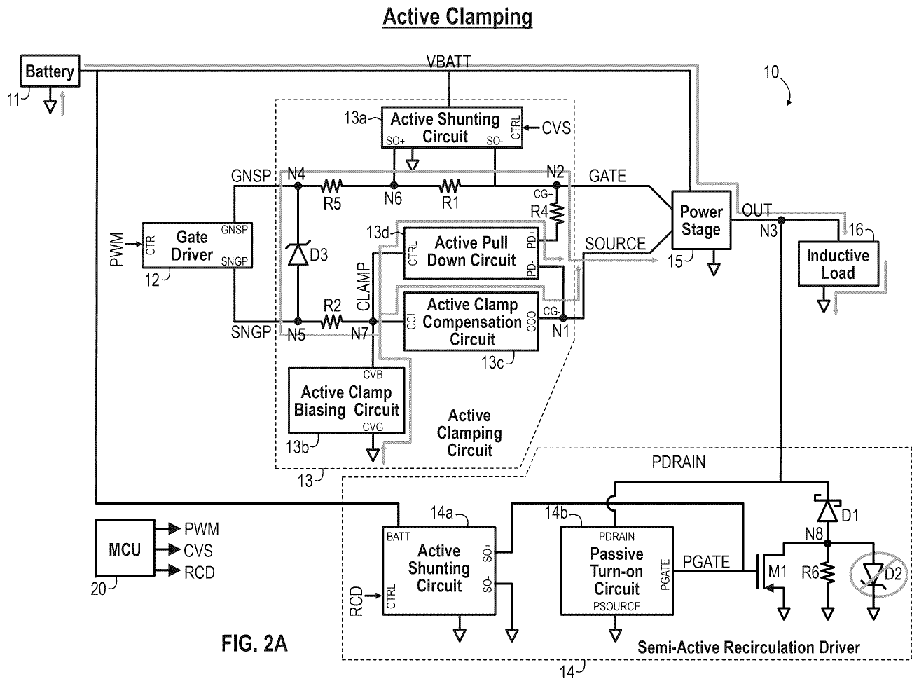

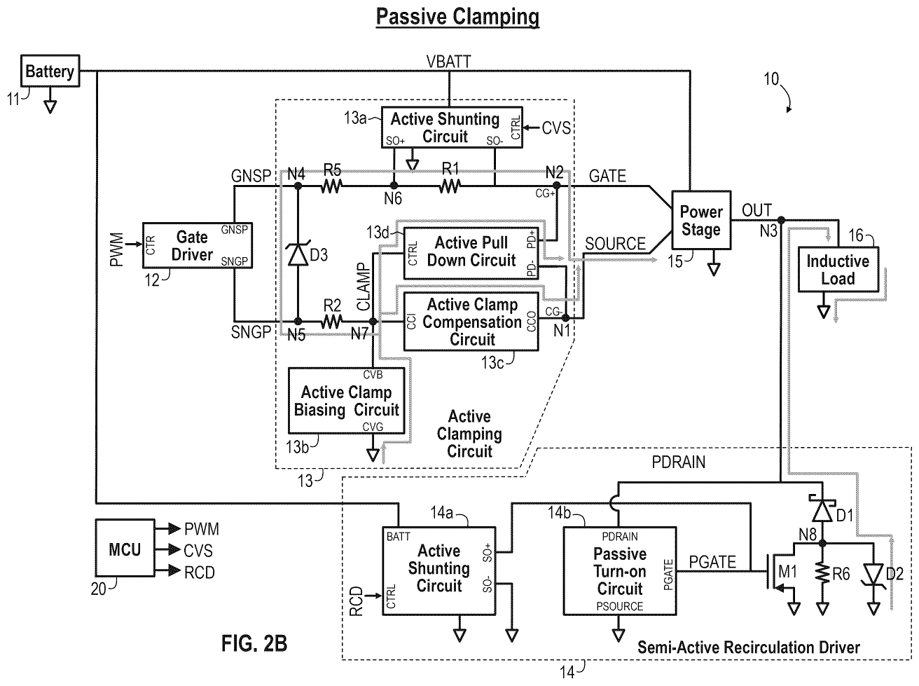

Further details of an example implementation of the inductive load driver 10 will be given with reference to FIG. 2. The gate driver 12 outputs control signals GNSP and SNGP to nodes N4 and N5 within the active clamping circuit 13.

The active clamping circuit 13 is now described and includes a Zener diode D3 having its cathode connected to node N4 and its anode connected to node N5. A resistor R5 is connected between nodes N4 and N6, a resistor R1 is connected between nodes N6 and N2; note that node N2 is connected to the gate terminal of the power stage 15. A resistor R2 is connected between nodes N5 and N7. An optional active shunting circuit 13a is coupled between the battery 11 and ground, has terminals connected to nodes N6 and N2, and is controlled by signal CVS received from microcontroller 20. An active clamp biasing circuit 13b is coupled between node N7 and ground. An active clamp compensation circuit 13c is coupled between nodes N7 and N1; note that node N1 is connected to the source terminal of the power stage 15. An active pull down circuit 13d is coupled between nodes N1 and node N2, with the coupling to node N2 being through resistor R4.

The semi-active recirculation driver 14 is coupled from ground to node N3 at the output OUT of the power stage 15. The semi-active recirculation driver 14 is now described, and includes a Schottky diode D1 having its cathode connected to node N3 and its anode connected to node N8. A Zener diode D2 (populated only for Passive Clamping hardware configuration) has its anode connected to node N8 and its cathode connected to ground. A (high impedance) resistor R6 is connected between node N8 and ground. A p-channel transistor M1 has its drain connected to node N8, its source connected to ground, and its gate coupled to receive the PGATE signal formed thereon. An active shunting circuit 14a has its output coupled between the node PGATE and ground, is controlled by the RCD signal received from MCU 20, and receives supply voltage from VBATT. A passive turn-on circuit 14b is coupled between node N3 and ground, and provides output to the gate of the p-channel transistor.

General operation to perform active clamping is now described with reference to FIG. 2A. Active clamping is generally preferable when the battery voltage VBATT is at a lower level (appreciably lower than the output clamping voltage, e.g., 36V), such as 12V, or, in some cases, 24V. Of note is that when the inductive load driver 10 is configured for active clamping, diode D2 is not populated in the device (e.g., is not present) and that resistor R6 in the semi-active recirculation driver 14 has a high resistance value.

To enable fast decay with active clamping, the active shunting circuit 14a turns off transistor M1, and the gate driver 12 shuts off (nodes GNSP and SNGP are low impedance shorted internally within gate driver 12). Energy dissipation occurs as current flows on a path from the inductive load 16, to ground, back to the battery 11, then through the power transistor of the power stage 15, and back to inductive load 16—this is the main recirculation path for energy dissipation during active clamping.

Another path for energy dissipation is from the inductive load 16, to ground, through the active clamp biasing circuit 13b to node N7. Assuming that the voltage at node N1, which is low impedance shorted to output OUT node through resistor R7 in power stage 15, is at a substantially negative value, for example −36V. Since ground is at 0V, the voltage at node N7 as a result of the current flow through the active clamp biasing circuit 13b will be a negative value that is less negative than the value at node N1, for example −5V. This creates a positive voltage differential between nodes N7 and N1. This voltage differential drives current flow through resistor R2 to node N5, and through Zener diode D3 to node N4. The current path continues through resistor R5 to node N6, through resistor R1 if the active shunting circuit 13a is deactivated via CVS to node N2 but from node N6 to node N2 if the active shunting circuit 13a is activated via CVS. The current path continues through resistor R4, through the active pull down circuit 13d, back to node N1. The action of the active pull down circuit 13d connecting the lower terminal of R4 to node N1 serves to establish a voltage between node N2 and node N1—the gate to source voltage—that maintains the power transistor within the power stage 15 in the saturation region during active clamping.

Further current flow caused by the voltage differential between nodes N7 and N1 is from node N7, through the active clamp compensation circuit 13c to node N1, and also from node N7 through the active pull down circuit 13d to node N1.

It should be appreciated that the majority of the energy dissipation during active clamping is through the inductive load 16 to ground, back to the battery 11, and through the output stage, as stated. The rest of the energy dissipation is in the active clamping circuit 13. As will be explained later when the specifics of the active clamp compensation circuit 13c are provided, the majority of the energy dissipated within the active clamping circuit 13 may be within the active clamp compensation circuit 13c, and the distribution between the power dissipation in the output stage 15 and the power dissipation in the active clamp compensation circuit 13c may be adjusted based on the single pulse energy handling capabilities of the power transistor within the power stage 15.

General operation to perform passive clamping is now described with reference to FIG. 2B. Passive clamping is generally preferable when the battery voltage VBATT is at a high level (higher than the output clamping voltage, e.g., 36V), such as 48V.

Of note is that when the inductive load driver 10 is configured for passive clamping, resistor R4 is not populated in the device (e.g., is not present and is instead replaced with a short), and Zener diode D2 in the semi-active recirculation driver 14 is populated.

To enable fast decay with passive clamping, the active shunting circuit 14a turns off transistor M1 and the gate driver 12 shuts off (nodes GNSP and SNGP are low impedance shorted internally within gate driver 12). Energy dissipation occurs as the inductive load current flowing on a path from the inductive load 16, to ground, and from ground through diode D2 to node N8, through Schottky diode D1, and back to the inductive load 16—this is the main path for energy dissipation during passive clamping.

It shall be noted that a very small portion of the inductive load current flows from the inductive load 16, to ground, through the active clamp biasing circuit 13b to node N7. Assuming that the voltage at node N1, which is low impedance shorted to output OUT node through resistor R7 in power stage 15, is at a substantially negative value, such as −36V, and since ground is at 0V, the voltage at node N7 as a result of the current flowing through the Active Clamp Biasing circuit 13b will be a negative value that is less negative than the value at node N1, for example 5V. This creates a positive voltage differential between nodes N7 and N1. This voltage differential drives current flow through resistor R2 to node N5, and though Zener diode D3 to node N4. The current path continues through resistor R5 to node N6, through resistor R1 if the active shunting circuit 13a is deactivated via CVS to node N2 but from node N6 to node N2 if the active shunting circuit 13a is activated via CVS. The current path continues through the active pull down circuit 13d, back to node N1. The action of the active pull down circuit 13d pulling down node N2 to node N1 serves to short the gate and source of the power transistor in the power stage 15. This turns off the power transistor in the power stage 15 and maintains the power transistor in the power stage 15 as being in the cutoff region during passive clamping, so that, as stated, the majority of energy dissipation is through diodes D2 and D1.

Further current flow caused by the voltage differential between nodes N7 and N1 is from node N7, through the active clamp compensation circuit 13c to node N1, and also from node N7 through the active pull down circuit 13d to node N1. But energy dissipation by these two paths is significantly lower compared to that through diodes D2 and D1.

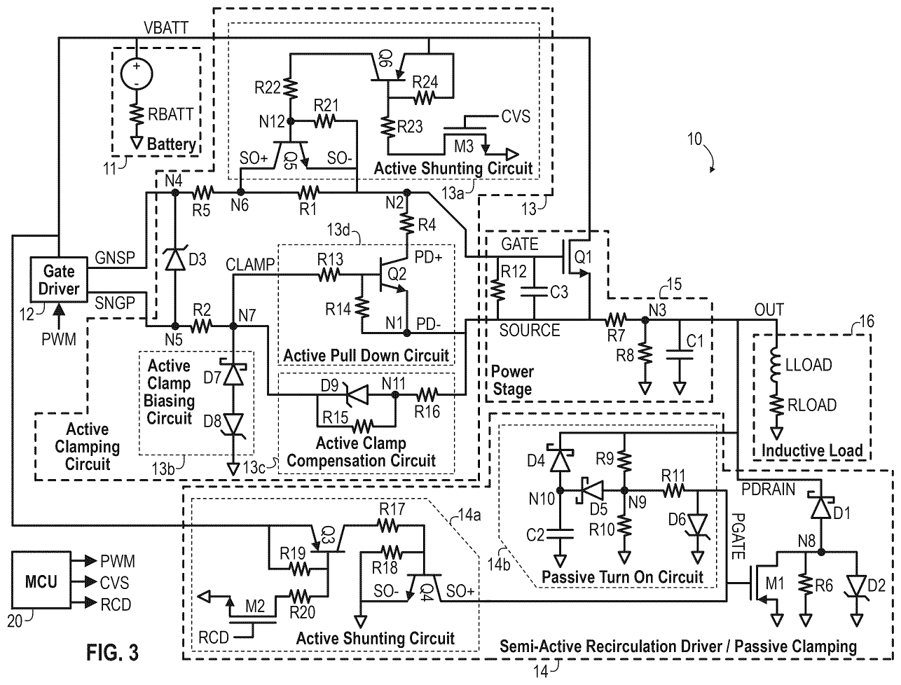

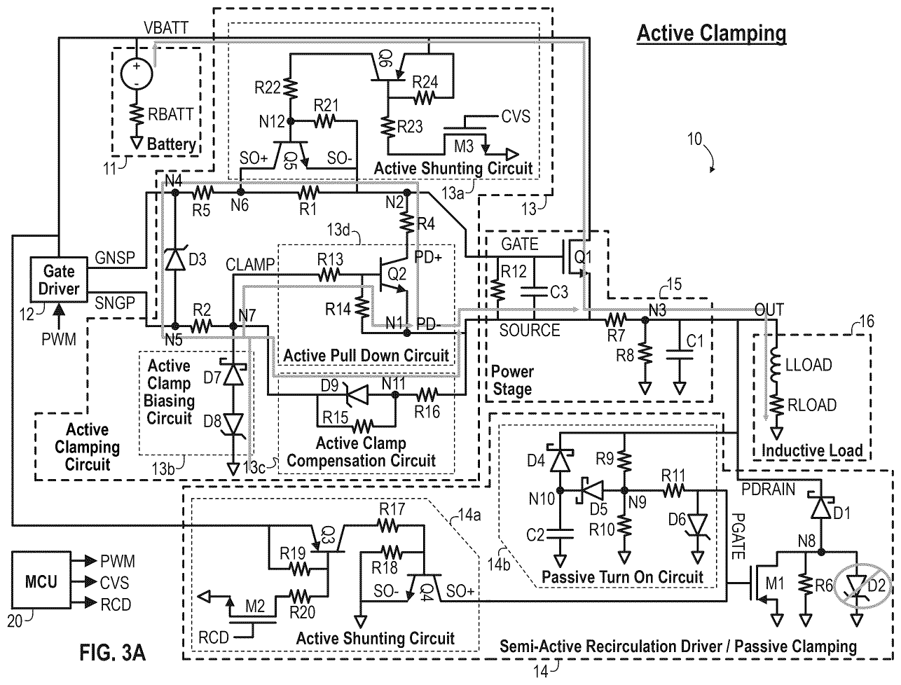

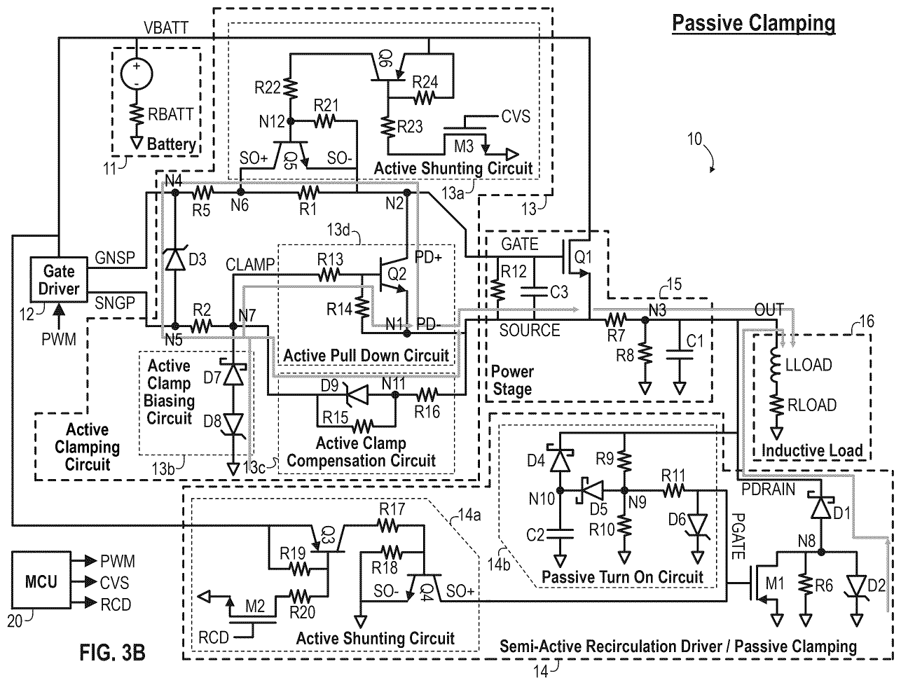

An example full component level implementation is now described with reference to FIG. 3.

The power stage 15 includes an n-channel power transistor Q1 having its drain coupled to receive the battery voltage VBATT from the battery 11, its source connected to node N1, and its gate connected to node N2. Also included is a resistor R12 connected between nodes N2 and N1, a capacitor C3 connected between nodes N2 and N1, a resistor R7 connected between nodes N1 and N3, a resistor R8 connected between nodes N3 and ground, and a capacitor C1 connected between node N3 and ground.

The gate driver 12 may be any suitable driver understood by one of ordinary skill in the art and is coupled to provide control signal GNSP to node N4 and provide control signal SNGP to node N5.

The active clamping circuit 13 includes a Zener diode D3 with its cathode connected to node N4 and its anode connected to node N5, with resistor R5 connected between nodes N4 and N6, resistor R1 connected between nodes N6 and N2, and resistor R2 connected between nodes N5 and N7. The active clamping circuit 13 includes an active shunting circuit 13a connected to the battery 11, node N6, and node N2, an active clamp biasing circuit 13b connected between nodes N7 and ground, an active clamp compensation circuit 13c connected between nodes N7 and N1, and an active pull down circuit 13d connected between nodes N2 and N1, with the connection to node N2 being through resistor R4.

The active shunting circuit 13a includes NPN transistor Q5 having its emitter connected to node N2, its collector connected to node N6, and its base connected to node N12. The active shunting circuit 13a further includes resistor R21 connected between nodes 12 and N2, and resistor R22 connected between node N12 and the collector of PNP transistor Q6. PNP transistor Q6 has its emitter connected to the battery 11 and has its base connected to its emitter through resistor R24 as well as to the drain of n-channel transistor M3 through resistor R23. N-channel transistor M3 has its source connected to ground and its gate coupled to receive the CVS signal.

The active clamp biasing circuit 13b includes Schottky diode D7 having its cathode connected to node N7 and its anode connected to the anode of Zener diode D8, which has its cathode connected to ground.

The active clamp compensation circuit 13c includes resistor R16 connected between node N1 and node N1, resistor R15 connected between node N7 and node N11, Zener diode D9 having its anode connected to node N11 and its cathode connected to node N7.

The active pull down circuit 13d includes NPN transistor Q2 having its collector connected to resistor R4, its emitter connected to node N1, and its base connected to its emitter through resistor R14. Resistor R13 is connected between the base of Q2 and node N7.

The semi-active recirculation driver 14 includes an active shunting circuit 14a connected between the battery 11 and the gate of p-channel transistor M1, and a passive turn on circuit 14b connected between the gate of p-channel transistor M1 and node N3. P-channel transistor M1 has its drain connected to node N8 and its source connected to ground. A resistor R6 is connected between node N8 and ground, and a Zener diode D2 has its anode connected to node N8 and its cathode connected to ground. A Schottky diode D1 has its anode connected to node N8 and its cathode connected to node N3.

The active shunting circuit 14a includes NPN transistor Q4 having its collector connected to the gate of p-channel transistor M1, having its emitter connected to ground, and having its base connected to ground through resistor R18. The active shunting circuit 14a further includes resistor R17 connected between the base of NPN transistor Q4 and the collector of PNP transistor Q3. The emitter of PNP transistor Q3 is connected to the battery 11, and is connected to its base through resistor R19. Resistor R20 is connected between the base of PNP transistor Q3 and the drain of n-channel transistor M2. The source of n-channel transistor M2 is connected to ground, and the gate of n-channel transistor M2 is coupled to signal RCD.

The passive turn on circuit 14b includes a Schottky diode D4 having its cathode connected to node N3 and its anode connected to node N10. A capacitor C2 is connected between node N10 and ground. A resistor R9 is connected between node N3 and node N9, and a resistor R10 is connected between node N9 and ground. A Schottky diode D5 has its anode connected to node N9 and its cathode connected to node N10. A resistor R11 is connected between node N9 and the gate of p-channel transistor M1, and a Zener diode D6 has its anode connected to the gate of p-channel transistor M1 and its cathode connected to ground.

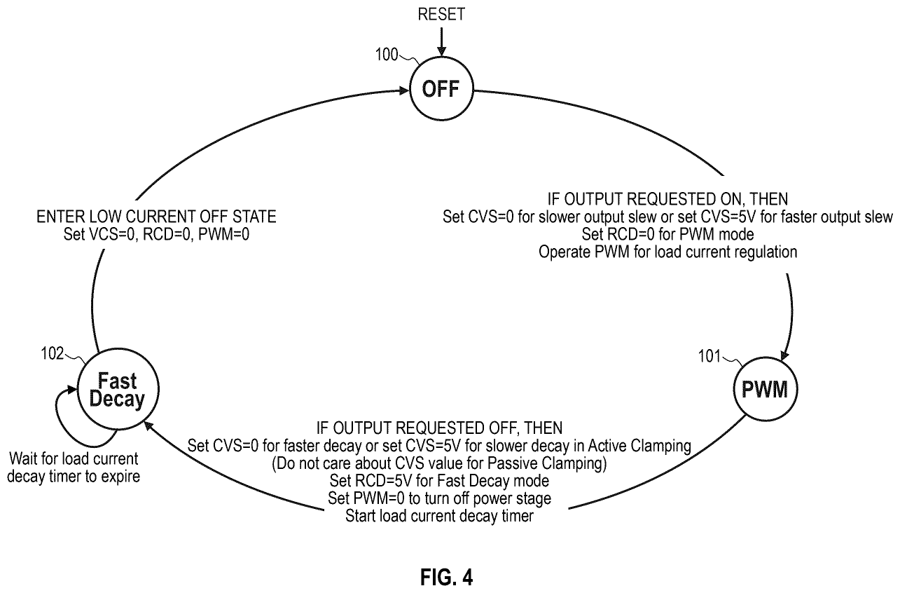

More detailed operation will now be described with additional reference to the state diagram of FIG. 4 showing operation of the MCU 20 of FIGS. 2-3.

Starting from an initial condition (State 100), a power-on reset (or a power-on in the case of startup) is performed by the MCU 20, and MCU 20 then proceeds to start operation in PWM mode. Here, the MCU 20 deasserts RCD to activate PWM load current circulation and generates the PWM signal so as to cause the gate driver 12 to suitably drive the power stage 15 to supply the inductive load 16 in PWM mode (State 101).

Referring now to the semi-active recirculation driver 14, the deassertion of RCD by the MCU 20 at State 101 turns n-channel transistor M2 off, which has the effect of turning off PNP transistor Q3 so that NPN Q4 remains off. During the off-periods of the PWM, a low impedance path is formed through the ground connection between the inductive load 16 and the capacitor C2, and through D4. This serves to charge capacitor C2 with a negative voltage, which ultimately serves to provide a negative voltage at the gate of M1, turning transistor M1 on during PWM.

Also at State 101, the MCU 20 may deassert CVS for a slower output slew rate or assert CVS for a faster output slew. Referring to the active clamping circuit 13, the deassertion of CVS serves to turn off n-channel transistor M3, having the effect of turning off PNP transistor Q6, and in turn, turning off NPN transistor Q5 so that resistor R1 remains in the path between the gate of n-channel transistor Q1 and the GNSP pin of the gate driver 12. On the other hand, the assertion of CVS serves turn on n-channel transistor M3 to sink current from the base of PNP transistor Q6 to turn Q6 on, thereby sourcing current to the base of NPN transistor Q5 to turn Q5 on to shunt across resistor R1, removing resistor R1 from the path between the gate of n-channel transistor Q1 and the GNSP pin of the gate driver 12.

If load conditions change, or if a command is received to turn-off, then operation proceeds to State 102 for operation in fast decay mode, using either active clamping or passive clamping. To facilitate this, the MCU 20 asserts RCD and deasserts PWM to turn-off the power stage 15. Referring to the semi-active recirculation driver 14, the assertion of RCD by the MCU 20 turns on n-channel transistor M2, which then pulls the base of PNP transistor Q3 low to turn on Q3. As a result, transistor Q3 sources current to the base of NPN transistor Q4 to turn on Q4, which then shorts the gate of p-channel transistor M1 to ground, turning off transistor M1.

Fast decay in either active clamping or passive clamping can then proceed. Fast decay in active clamping will now be described with reference to FIG. 3A. The gate driver 12 shuts off (nodes GNSP and SNGP are low impedance shorted internally within gate driver 12), and energy dissipation occurs as current flows on a path from the inductive load 16, to ground, back to the battery 11, then through the power transistor Q1 of the power stage 15, and back to inductive load 16—this is the main recirculation path for energy dissipation during active clamping.

Another path for energy dissipation is from the inductive load 16, to ground, then from ground up through Zener diode D8 and Schottky diode D7. Assuming that the voltage at node N1 is at a substantially negative value, since ground is at 0V, the voltage at node N7 as a result of the current flow through diodes D7 and D8 will be a negative value that is less negative than the value at node N1. This creates a positive voltage differential between nodes N7 and N1. This voltage differential drives current flow through resistor R2 to node N5, and through Zener diode D3 to node N4. The current path continues through resistor R5 to node N6, through resistor R1 if the active shunting circuit 13a is deactivated via CVS to node N2 but from node N6 to node N2 if the active shunting circuit 13a is activated CVS. The current path continues through resistor R4, through NPN transistor Q2 back to node N1. The connection of the lower terminal of R4 to node N1 by transistor Q2 serves to establish a voltage between node N2 and node N1—the gate to source voltage—that maintains the power transistor within the power stage 15 in the saturation region during active clamping.

Further current flow caused by the voltage differential between nodes N7 and N1 is from node N7, through Zener diode D9, resistor R15, and resistor R16 to node N1, and also from node N7 through resistors R13, R14, and the base-emitter junction of Q2 (which turns on Q2 and drives it into saturation region) to node N1.

Of interest in active clamping is that, in the active clamp compensation circuit 13c, the lower the resistance value of R16, the greater the amount of energy dissipated in resistor R16, and consequently the lower the amount of energy dissipated by the power transistor Q1. This way, the value of R16 can be tuned to match the power transistor Q1 so that, overall, the requisite energy dissipation can be met during active clamping. The addition of D9 and R15 is optional and serves to accelerate the decay of the tail current after Q1 exits the saturation region and enters cut off region at the end of the active clamping. For simplicity, all simulations are run assuming D9 and R15 are short circuited.

Fast decay in passive clamping will now be described with reference to FIG. 3B. The gate driver 12 shuts off (nodes GNSP and SNGP are low impedance shorted internally within gate driver 12). Energy dissipation occurs as the inductive load current flowing on a path from the inductive load 16, to ground, and from ground through Zener diode D2 to node N8, through Schottky diode D1, and back to the inductive load 16—this is the main path for energy dissipation during passive clamping.

A small portion of the inductive load current flows from the inductive load 16, to ground, through Zener diode D8 and Schottky diode D7 to node N7. Assuming that the voltage at node N1 is at a substantially negative value, and since ground is at 0V, the voltage at node N7 will therefore be a negative value that is less negative than the value at node N1. This creates a positive voltage differential between nodes N7 and N1. This voltage differential drives current flow through resistor R2 to node N5, and though Zener diode D3 to node N4. The current path continues through resistor R5 to node N6, through resistor R1 if the active shunting circuit 13a is deactivated via CVS to node N2 but from node N6 to node N2 if the active shunting circuit 13a is activated via CVS. The current path continues through NPN transistor Q2 (without the presence of resistor R4, which is not populated for passive clamping), back to node N1. The action of the NPN transistor Q2 pulling down node N2 to node N1 serves to short the gate and source of the power transistor in the power stage 15. This turns off the power transistor in the power stage 15 and maintains the power transistor in the power stage 15 as being in the cutoff region during passive clamping, so that, as stated, the majority of energy dissipation is through diodes D2 and D1.

Further current flow caused by the voltage differential between nodes N7 and N1 is from node N7, through the Zener diode D9, resistor R15, and resistor R16 to node N1, and also from node N7 through resistors R13, R14, and the base-emitter junction of Q2 (which turns on Q2 and drives it into saturation region) to node N1. But energy dissipation by these two paths is significantly lower compared to that through diodes D2 and D1.

The clamping voltage in the active clamping hardware configuration can be selected by the microcontroller 20. For a first, higher clamp voltage, the microcontroller 20 deasserts CVS, so that n-channel transistor M3 is turned off, having the effect of turning off PNP transistor Q6, and in turn, turning off NPN transistor Q5. For a second, lower clamp voltage, the microcontroller 20 asserts CVS, turning on n-channel transistor M3 to sink current from the base of PNP transistor Q6 to turn Q6 on, thereby sourcing current to the base of NPN transistor Q5 to turn Q5 on to shunt across resistor R1.

At the beginning of State 102, a load current decay timer is started, and once the load decay timer times out (e.g., reaches a desired value), operation proceeds back to the off or reset condition of State 100, in which the MCU 20 deasserts PWM, VCS, and RCD.

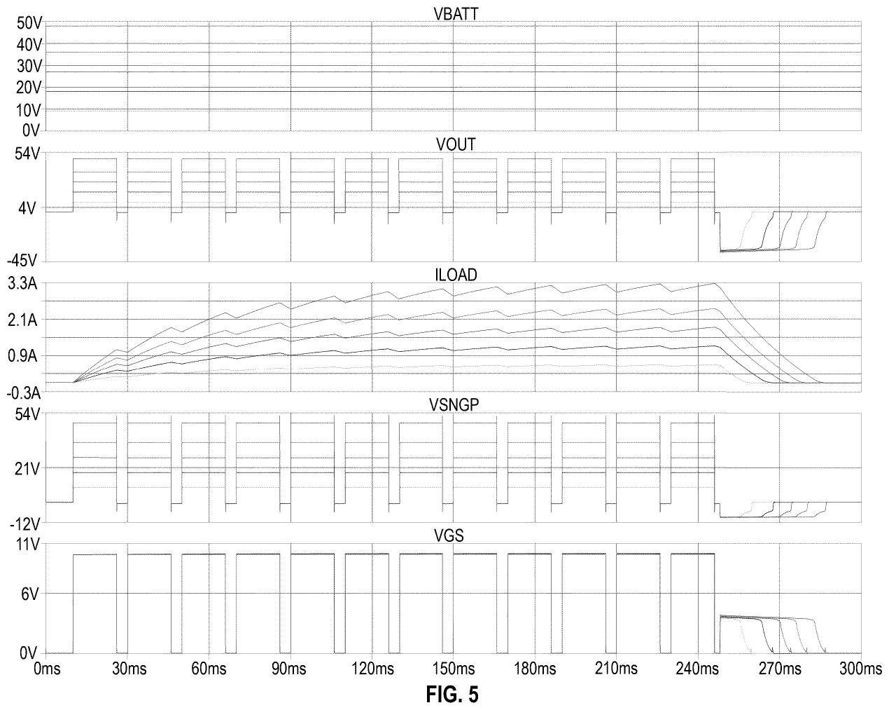

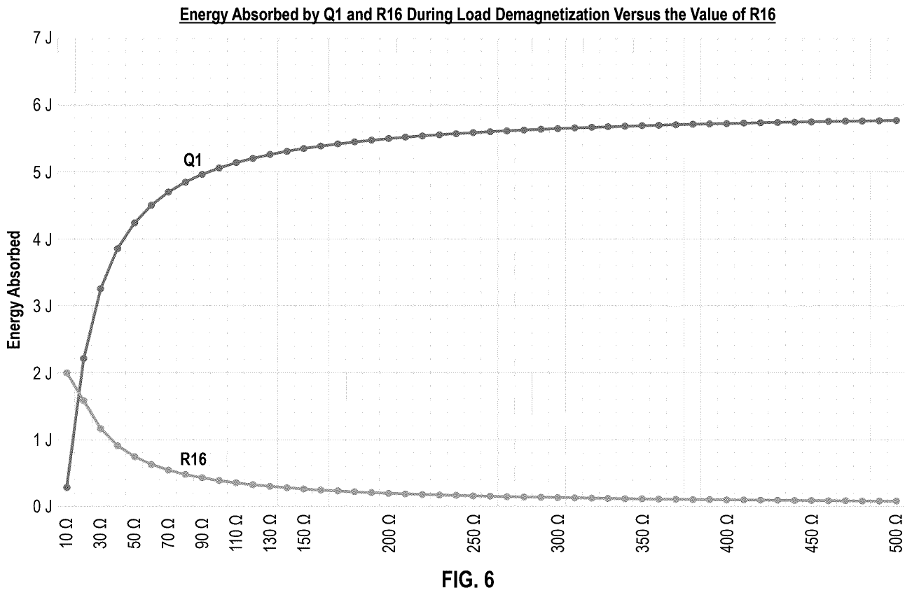

Waveforms showing the effectiveness of the inductive load driver 10 in the active clamping hardware configuration may be found in FIG. 5, where the clamping of the output voltage (marked as VOUT in FIG. 5) of power stage 15 and the clamping of the SNGP voltage (marked as VSNGP in FIG. 5) of the gate driver 12 are presented along with a few other circuit parameters (VBATT for the battery voltage; ILOAD for the inductive load current; VGS for the gate to source voltage of the output stage transistor). Thus, in the active clamping hardware configuration, the inductive load driver 10 allows maintaining the voltage at the pins of the gate driver 12 within their absolute maximum ratings, while, as described, providing for on-the-fly selection between fast decay mode and PWM mode, and providing for dynamic selection from between two different clamping voltages. Additionally, recall that the proportion of energy dissipated by transistor Q1 and resistor R16 in active clamping hardware configuration may be altered by changing the resistance value of R16. This relationship is shown in FIG. 6, where it can be seen that as the resistance value of R16 becomes lower (particularly as it becomes lower than 70Ω or so), the proportion of power dissipated by R16 increases, with the crossover point being around 10Ω.

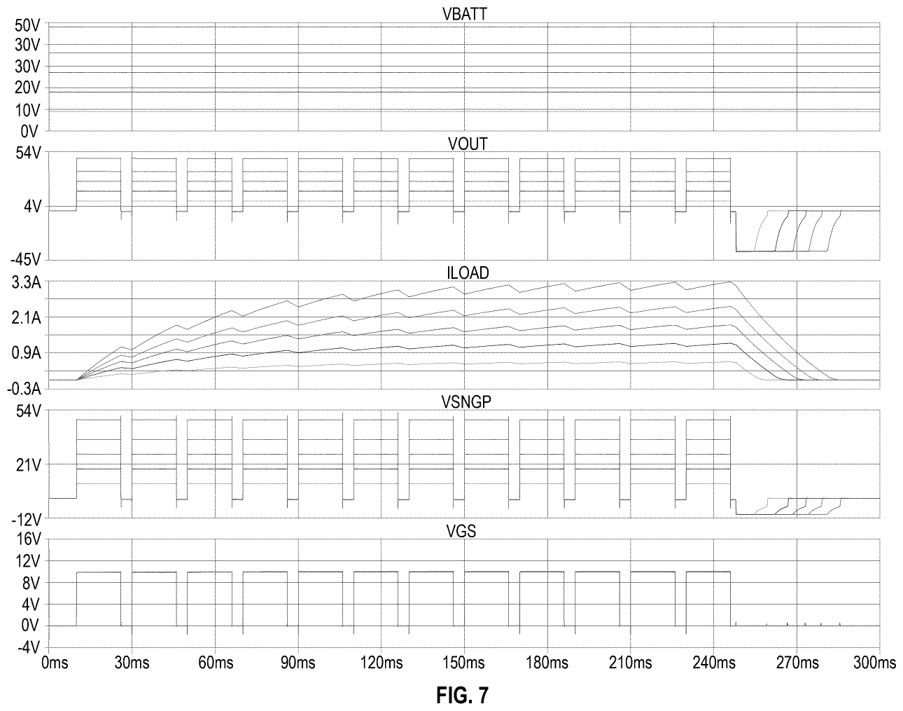

Waveforms showing the effectiveness of the inductive load driver 10 in the passive clamping hardware configuration may be found in FIG. 7, where the clamping of the output voltage (marked as VOUT in FIG. 7) of power stage 15 and the clamping of the SNGP voltage (marked as VSNGP in FIG. 7) of the gate driver 12 are presented along with a few other circuit parameters (VBATT for the battery voltage; ILOAD for the inductive load current; VGS for the gate to source voltage of the output stage transistor). Thus, in the passive clamping hardware configuration the inductive load driver 10 also allows maintaining the voltage at the pins of the gate driver 12 within their absolute maximum ratings, while, as described, providing for on-the-fly selection between fast decay mode and PWM mode.

For active clamping, the output voltage VOUT at the output OUT of the power stage 15 in fast decay mode may be mathematically represented as:

$$VOUT = VCLAMP - \frac{VGS - VCE}{R 4} \times R2 - VFD 3 - \frac{VGS - VCE}{R 4} \times ( R 1 + R 5 ) - VGS$$

Where VCLAMP is the voltage at node N7 (also labelled as node CLAMP), VGS is the gate to source voltage of transistor Q1 operating in the saturation region when the inductive load 16 is turned off (e.g., load demand ceases) in the fast decay mode, VFD3 is the forward voltage across Zener diode D3, and VCE is the collector to emitter voltage of transistor Q2 operating in the saturation region. The above equation assumes that CVS is deasserted; otherwise R1 would be shorted through by the active shunting circuit 13a (i.e., R1=0 in the above equation).

If R2=R4 and (R1+R5)=k×R4, then the equation can be simplified and written in terms of the desired output clamping voltage:

$$k = \frac{VOUT - VCLAMP + 2 \times VGS - VCE + VFD 3}{VCE - VGS}$$

For passive clamping, the output voltage VOUT at the output OUT of the power stage 15 in fast decay mode is primarily determined by D2.

Finally, it is evident that modifications and variations can be made to what has been described and illustrated herein without departing from the scope of this disclosure.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. An inductive load driver, comprising:
a power stage including a power transistor having a gate terminal, a source terminal, and a drain terminal, the drain terminal coupled to receive a supply voltage and an output node configured to drive an inductive load;
a gate driver having a gate-drive output terminal and a source-reference terminal, the gate-drive output terminal coupled to the gate terminal of the power transistor and the source-reference terminal coupled to the source terminal of the power transistor;
an active clamping circuit coupled between the gate terminal and the source terminal of the power transistor and also between the gate-drive output terminal and the source-reference terminal of the gate driver, wherein the active clamping circuit is configured to, in a first operating mode, pass a gate-drive voltage from the gate driver to the power transistor, and, in a second operating mode, clamp a voltage between the gate and source terminals to enable fast decay of current in the inductive load while limiting voltage excursions at the gate-drive output terminal and the source-reference terminal;
a recirculation driver coupled between ground and the output node of the power stage, wherein the semi-active recirculation driver is configured to, in the first operating mode, provide a low-impedance current-recirculation path and, in the second operating mode, provide a clamping path for fast-decay current recirculation; and
a controller configured to control the gate driver, the active clamping circuit, and the semi-active recirculation driver to selectively operate the inductive load driver in the first operating mode or the second operating mode;
wherein the active clamping circuit and the semi-active recirculation driver cooperate during the second operating mode to dissipate energy stored in the inductive load while maintaining voltages at the gate-drive output terminal and source-reference terminal of the gate driver within voltage limits.

2. The inductive load driver of claim 1, wherein the second operating mode comprises one of an active-clamping mode or a passive-clamping mode, and
wherein the controller is configured to select between the active-clamping mode and the passive-clamping mode based on a supply-voltage level or an operating condition.

3. The inductive load driver of claim 2,
wherein, in the active-clamping mode, the active clamping circuit comprises a Zener device and a plurality of resistors arranged to define an adjustable voltage differential between the gate terminal and the source terminal during the second operating mode.

4. The inductive load driver of claim 2,
wherein, in the active-clamping mode, the active clamping circuit further comprises an active pull-down circuit configured to establish a gate-to-source voltage that maintains the power transistor in a saturation region during the second operating mode.

5. The inductive load driver of claim 2,
wherein, in the passive-clamping mode, the semi-active recirculation driver comprises a Schottky diode and a Zener diode coupled to define an energy-dissipation path during the second operating mode.

6. The inductive load driver of claim 2,
wherein, in the active-clamping mode, the controller is configured to dynamically adjust a clamping voltage by enabling or disabling a shunting circuit that bypasses a resistor within the active clamping circuit.

7. The inductive load driver of claim 2,
wherein, in the active-clamping mode, the active clamping circuit includes a compensation circuit comprising a resistor having a resistance value selected to adjust a distribution of energy dissipation between the power transistor and the resistor.

8. The inductive load driver of claim 2,
wherein, in the passive-clamping mode, the semi-active recirculation driver comprises a p-channel transistor configured to selectively connect or disconnect a clamping network from the output node based on a control signal from the controller.

9. The inductive load driver of claim 2,
wherein the circuit is configured such that a majority of energy dissipation occurs through the power transistor during the active-clamping mode and through the diode network during the passive-clamping mode.

10. The inductive load driver of claim 2,
wherein the active-clamping and passive-clamping modes share common circuit nodes and differ by selective inclusion or omission of circuit components.

11. The inductive load driver of claim 1, wherein the controller is configured to operate in:
the first operating mode, which is a pulse-width-modulation (PWM) mode for load driving; and
the second operating mode, which is a fast-decay mode for current decay;
and to transition between the modes by coordinated control of the gate driver and the semi-active recirculation driver.

12. The inductive load driver of claim 1,
wherein the active clamping circuit and the semi-active recirculation driver are implemented so that negative voltage excursions at the gate-drive output terminal and source-reference terminal of the gate driver are clamped within voltage limits during the second operating mode.

13. A system comprising:
a microcontroller configured to generate control signals; and
the inductive load driver of claim 1,
wherein the microcontroller is configured to dynamically select between the first operating mode and either the active-clamping or passive-clamping embodiment of the second operating mode in response to load conditions or supply voltage.

14. A method for controlling an inductive load driver comprising a power transistor, a gate driver, and clamping circuits, the method comprising:
driving the power transistor in a first operating mode that provides pulse-width-modulated current to an inductive load;
upon termination of the first operating mode, switching to a second operating mode that performs fast current decay;
in the second operating mode, selectively operating in:
an active-clamping mode, wherein energy from the inductive load is dissipated through the power transistor and a clamping circuit coupled between the gate and source terminals; or
a passive-clamping mode, wherein energy from the inductive load is dissipated through a diode network coupled between the output node and ground; and
maintaining voltage levels at the gate-driver terminals within safe limits during operation in the second operating mode.

15. The method of claim 14,
wherein the fast-decay mode comprises either an active-clamping mode or a passive-clamping mode, and the method further comprises selecting between active-clamping mode and the passive-clamping mode based on a detected supply-voltage level or operating condition and operating in the selected mode.

16. The method of claim 15,
wherein operating in the active-clamping mode comprises maintaining the power transistor in a saturation region by applying a controlled gate-to-source voltage using an active pull-down circuit.

17. The method of claim 15,
wherein operating in the passive-clamping mode comprises recirculating inductive current through a Schottky diode and a Zener diode coupled between the output node and ground.

18. The method of claim 15,
further comprising adjusting a clamping voltage during the active-clamping mode by activating or deactivating a shunting circuit to bypass a resistor within the active clamping circuit.

19. The method of claim 15,
further comprising tuning an energy-dissipation ratio between the power transistor and a resistor in the clamping circuit by selecting a resistance value for the resistor.

20. The method of claim 14,
wherein, during the fast-decay mode, the method further comprises clamping negative voltage excursions at the gate-drive output terminal and source-reference terminal of the gate driver within voltage limits.

21. The method of claim 14,
further comprising transitioning back from the fast-decay mode to the pulse-width-modulation mode upon completion of a load-decay timer controlled by the controller.
